(19) United States
(12) Patent Application Publication
(10) Pub. No.: US 2026/0150699 A1
(43) Pub. Date: May 28, 2026

(54) SEMICONDUCTOR MODULE AND SEMICONDUCTOR MODULE SYSTEM

(71) Applicant: Mitsubishi Electric Corporation, Tokyo (JP)

(72) Inventors: Kazuki TAKAKURA, Tokyo (JP); Yuki MATSUTAKA, Tokyo (JP); Hodaka ROKUBUICHI, Tokyo (JP); Toshiya TADAKUMA, Tokyo (JP); Masaaki ISHINO, Tokyo (JP)

(73) Assignee: Mitsubishi Electric Corporation, Tokyo (JP)

(21) Appl. No.: 19/334,368

(22) Filed: Sep. 19, 2025

(30) Foreign Application Priority Data
Nov. 28, 2024 (JP) 2024-207337

(51) Int. Cl. H01L 23/62; H01L 23/00; H01L 23/495; H01L 25/065; H01L 25/16; H02M 1/34; H02M 1/42; H02M 7/00; H02M 7/5387

(52) U.S. Cl. CPC H10W 42/80; H02M 1/346; H02M 1/4233; H02M 7/003; H10W 70/442; H10W 90/00; H10W 90/811; H02M 7/5387; H10W 70/465; H10W 70/475; H10W 90/756

(57) ABSTRACT

Included in a semiconductor module are: a first frame that is connected to a lower-surface electrode of a first semiconductor chip; a second frame that is connected to an upper-surface electrode of a second semiconductor chip; a third frame that is connected to the upper-surface electrode of the first semiconductor chip and the lower-surface electrode of the second semiconductor chip; and fourth and fifth terminals that are connected to gate electrodes of the first and second semiconductor chips, and protrude from the semiconductor module. The semiconductor module has at least either first opposing portions parallel to a current-flowing direction in the second and third frames, or second opposing portions parallel to the current-flowing direction in the first frame of one of adjacent semiconductor chip groups and the second frame of the other one of the adjacent semiconductor chip groups.

### BACKGROUND

### Technical Field

The present disclosure relates to a semiconductor module, and more particularly, to a semiconductor module with a reduced surge voltage.

### Description of the Background Art

In a case where a semiconductor device is driven at a high frequency, it is essential to reduce switching loss. To reduce switching loss, it is necessary to increase the switching speed.

For example, FIG. 1C of International Publication No. 2023/037809 discloses a configuration of a semiconductor module including a switching element, in which a path member in which a reverse recovery current and a gate current flow is provided so as to generate a mutual induction current, to reduce switching loss when the switching element is turned on, and the switching speed when the switching element is turned on is increased.

According to International Publication No. 2023/037809, it is possible to reduce the switching loss when the switching element is turned on, but a decrease in the surge voltage when the switching element is turned off has not been considered.

### SUMMARY

The present disclosure aims to provide a semiconductor module that has a reduced surge voltage at a time of turning off a switching element.

A semiconductor module according the present disclosure includes a plurality of semiconductor chip groups each including a first semiconductor chip and a second semiconductor chip that are connected in series between a first power line to which a first voltage is supplied and a second power line to which a second voltage lower than the first voltage is supplied, and perform switching complementarily, in which each of the semiconductor chip groups includes: a first frame that is connected to a lower-surface electrode of the first semiconductor chip, and includes a first terminal that is a portion protruding from the semiconductor module to outside; a second frame that is connected to an upper-surface electrode of the second semiconductor chip, and includes a second terminal that is a portion protruding from the semiconductor module to the outside; a third frame that is connected to an upper-surface electrode of the first semiconductor chip and a lower-surface electrode of the second semiconductor chip, and includes a third terminal that is a portion protruding from the semiconductor module to the outside; a fourth terminal that is connected to a gate electrode of the first semiconductor chip, and protrudes from the semiconductor module to the outside; and a fifth terminal that is connected to a gate electrode of the second semiconductor chip, and protrudes from the semiconductor module to the outside, and the semiconductor module has at least either first opposing portions disposed so as to be parallel to a current-flowing direction in the second frame and the third frame, or second opposing portions disposed so as to be parallel to the current-flowing direction in the first frame of one of adjacent semiconductor chip groups of the plurality of semiconductor chip groups and in the second frame of the other one of the adjacent semiconductor chip groups.

A semiconductor module according to the present disclosure has first opposing portions and/or second opposing portions, and thus, can reduce the surge voltage at a time of turning off a first semiconductor chip and a second semiconductor chip that are switching elements.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration of a semiconductor module according to a first preferred embodiment;

FIG. 2 is a plan view visually illustrating first opposing portions in the semiconductor module according to the first preferred embodiment;

FIG. 3 is a plan view visually illustrating an extended portion of a frame in the semiconductor module according to the first preferred embodiment;

FIG. 4 is a plan view visually illustrating second opposing portions in the semiconductor module according to the first preferred embodiment;

FIGS. 5 and 6 are plan views each illustrating an example of the position of a snubber capacitor in the semiconductor module according to the first preferred embodiment;

FIG. 7 is a diagram illustrating an example of external circuits in a case where a snubber capacitor is provided for each phase;

FIG. 8 is a diagram illustrating an example of external circuits in a case where one snubber capacitor is used in the three phases;

FIG. 9 is a diagram illustrating an example of external circuits in a case where one semiconductor module is used as a semiconductor module for one phase;

FIG. 10 is a conceptual diagram illustrating an example in which two semiconductor modules are connected in parallel;

FIG. 11 is a plan view illustrating a configuration of a semiconductor module according to a first modification of the first preferred embodiment; and

FIG. 12 is a block diagram illustrating a configuration of a semiconductor module system according to a second preferred embodiment of the present disclosure.

### DESCRIPTION OF THE PREFERRED EMBODIMENTS

### First Preferred Embodiment

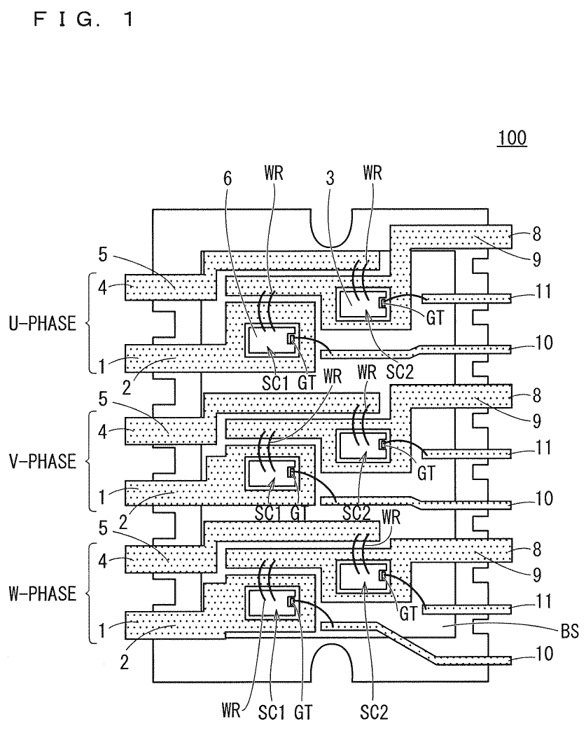

FIG. 1 is a plan view illustrating a configuration of a semiconductor module 100 according to a first preferred embodiment of the present disclosure, and illustrates an internal configuration with a resin package PG partially omitted for convenience.

As illustrated in FIG. 1, in a semiconductor module 100, a plurality of semiconductor chips SC1 and a plurality of semiconductor chips SC2 are mounted on a plurality of frames provided on an insulating member BS.

FIG. 1 illustrates an example of a circuit that can be used as a three-phase full-bridge inverter, and the U-phase, V-phase, and W-phase inverters all have the same configuration.

For example, the U-phase inverter includes a semiconductor chip SC1 (first semiconductor chip) and a semiconductor chip SC2 (second semiconductor chip) connected in series between a power line (first power line) that is connected to a positive terminal of a direct-current power supply (not shown) and is supplied with a positive voltage (first voltage) and a power line (second power line) that is connected to a negative terminal and is supplied with a negative-positive voltage (second voltage).

The semiconductor chip SC1 is mounted on a frame 2 (first frame) forming a circuit pattern, and the semiconductor chip SC2 is mounted on a frame 9 (third frame). In the semiconductor chips SC1 and SC2, upper-surface electrodes are emitter electrodes 6 and 3, respectively, and lower-surface electrodes are collector electrodes.

One end of the frame 2 protrudes outward as an upper arm collector terminal 1 (first terminal) from a resin package PG, and one end of the frame 9 protrudes outward as an upper arm emitter terminal/lower arm collector terminal 8 (third terminal) from the resin package PG, and serves as an output terminal of the U-phase inverter. The upper arm collector terminal 1 and the upper arm emitter terminal/lower arm collector terminal 8 protrude from side surfaces of the resin package PG on the opposite side from each other.

The emitter electrode 6 of the semiconductor chip SC1 is electrically connected to the frame 9 (third frame) via a wire WR, and the emitter electrode 3 of the semiconductor chip SC2 is electrically connected to a frame 5 (second frame) via a wire WR.

The frame 5 has a portion parallel to the frame 2, and one end of the frame 5 protrudes outward as a lower arm emitter terminal 4 (second terminal) from the resin package PG. The lower arm emitter terminal 4 and the upper arm collector terminal 1 protrude from the same side surface of the resin package PG.

The frame 5 has a portion parallel to the frame 2 and a portion parallel to the frame 9, and is electrically connected to the emitter electrode 3 of the semiconductor chip SC2 via the wire WR at the portion parallel to the frame 9.

The semiconductor chip SC1 has a gate electrode GT on the upper surface, and the gate electrode GT is electrically connected to a control terminal 10 (fourth terminal) via a wire WR.

The semiconductor chip SC2 has a gate electrode GT on the upper surface, and the gate electrode GT is electrically connected to a control terminal 11 (fifth terminal) via a wire WR.

The one end of each of the control terminals 10 and 11 protrudes from the same side surface of the resin package PG as the upper arm emitter terminal/lower arm collector terminal 8. In the above description, the semiconductor chips SC1 and SC2 are assumed to be reverse conducting IGBTs (RC-IGBTs) in which an insulated gate bipolar transistor (IGBT) and a freewheeling diode (FWD) are provided on the same semiconductor substrate. However, the semiconductor chips SC1 and SC2 are not necessarily RC-IGBTs, and may be IGBTs, MOS field effect transistors (MOSFETs), or the like. Also, the semiconductor substrate is not necessarily a silicon substrate, and a silicon carbide (SiC) substrate can also be adopted.

The configuration of the U-phase inverter described above is the same as the configurations of the V-phase and W-phase inverters, the same components are denoted by the same reference numerals, and the same explanation will not be repeated. In the following, features of the semiconductor module 100 illustrated in FIG. 1 are described.

### Feature 1

The upper arm collector terminals 1 (first terminals) and the lower arm emitter terminals 4 (second terminals) of a plurality of semiconductor chip groups forming the inverters of the respective phases protrude alternately side by side from one side surface of the semiconductor module 100, and the upper arm emitter terminals/lower arm collector terminals 8 (third terminals), the control terminals 10 (fourth terminals), and the control terminals 11 (fifth terminals) protrude alternately side by side from the other side surface opposite from the one side surface of the semiconductor module 100.

As illustrated in FIG. 1, in each semiconductor chip group in the semiconductor module 100, the frame 5 (second frame) and the frame 9 (third frame) have opposing portions arranged so as to be parallel to the current-flowing directions.

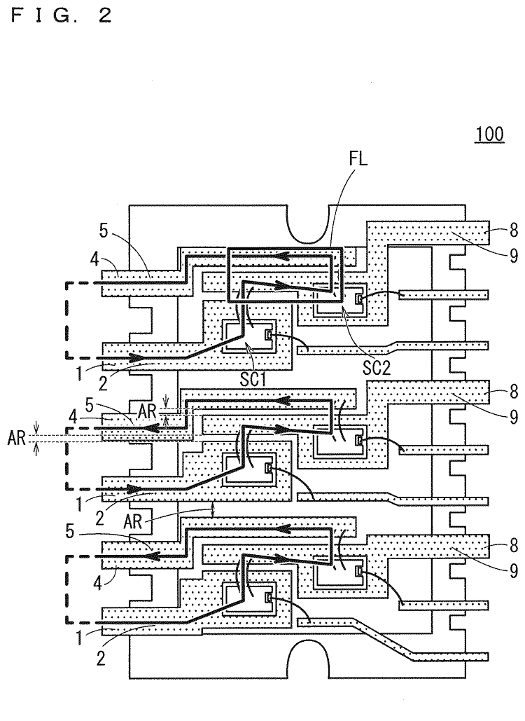

These portions are illustrated visually in FIG. 2. FIG. 2 illustrates the same semiconductor module 100 as that in FIG. 1, but only the relevant portions are denoted by reference numerals and are simplified. In FIG. 2, the frame 5 and the frame 9 in the region indicated by a frame line FL are the opposing portions (first opposing portions) arranged so as to be parallel to the current-flowing directions, the current flows indicated by arrows or the directions in which the current flows from the upper arm collector terminal 1 to the lower arm emitter terminal 4 are opposite to each other, and the magnetic fluxes generated by the current flows cancel each other. Thus, parasitic inductance can be reduced. Accordingly, the surge voltage to be generated from parasitic inductance can be reduced.

### Feature 2

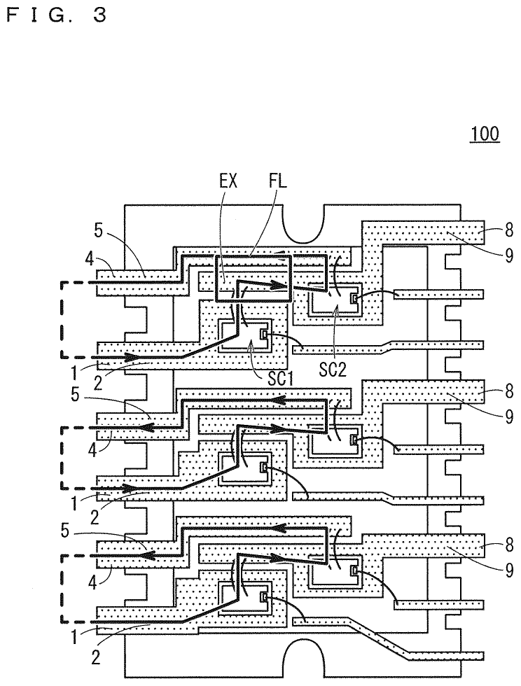

In FIG. 2, in the region indicated by the frame line FL, the frame 9 is intentionally provided with an extended portion so that the length of the opposing portions of the frame 5 and the frame 9 is maximized. These portion is illustrated visually in FIG. 3.

In FIG. 3, the frame 9 in the region indicated by a frame line FL is an extended portion EX, and extends from the portion at which the semiconductor chip SC2 is mounted on the frame 9 so as to be parallel to the frame 5. As compared with that in a case where the extended portion EX is not provided, the effect of canceling the magnetic fluxes with each other is enhanced, and the effect of reducing parasitic inductance is enhanced.

### Feature 3

As illustrated in FIG. 1, between semiconductor chip groups adjacent to each other, the frame 2 (first frame) of one adjacent semiconductor chip group and the frame 5 (second frame) of the other adjacent semiconductor chip group have opposing portions arranged so as to be parallel to each other's current-flowing direction.

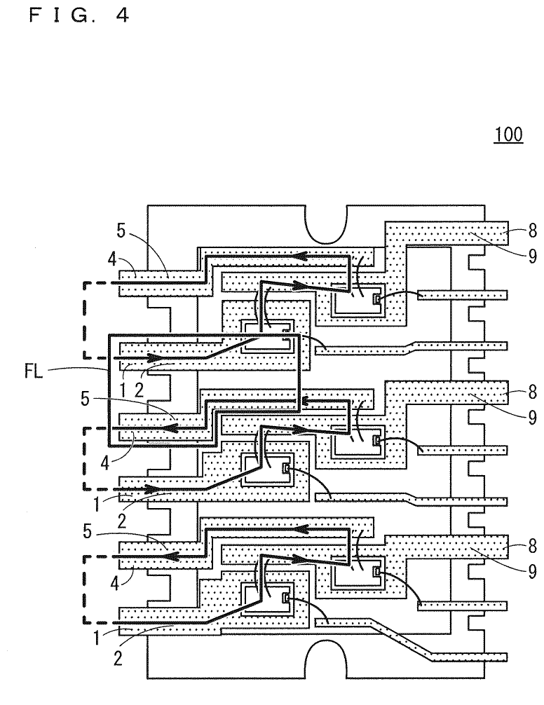

These portion is illustrated visually in FIG. 4. FIG. 4 illustrates the same semiconductor module 100 as that in FIG. 1, but only the relevant portions are denoted by reference numerals and are simplified. In FIG. 4, the frame 2 and the frame 5 in the region indicated by a frame line FL are the opposing portions (second opposing portions) arranged so as to be parallel to the current-flowing directions, the current flows indicated by arrows or namely the current flowing directions are opposite to each other, and the magnetic fluxes generated by the current flows cancel each other. Thus, parasitic inductance can be reduced. Accordingly, the surge voltage to be generated from parasitic inductance can be reduced.

### Feature 4

As described with reference to FIGS. 2 and 4, the distance between opposing frames is minimized at the opposing portions in which the frames are arranged to be parallel to the current-flowing directions.

In FIG. 2, the distance between opposing frames is schematically shown by arrows AR. Specifically, the shortest distance is set so that the portion between the frame 5 and the frame 9 of one semiconductor chip group, the portion between the frame 9 and the frame 2, and the portion indicated by the arrows AR between the frame 2 of one adjacent semiconductor chip group and the frame 5 of the other adjacent semiconductor chip group each have an insulation distance that can ensure the withstand voltage required by the voltage rating of the semiconductor module 100.

For example, when the withstand voltage of the semiconductor module 100 is 600 to 1200 V, the shortest distance is set to about 1 to 5 mm. By narrowing the distance between opposing frames as much as possible, the effect of mutually canceling the magnetic fluxes generated by current flows can be further enhanced.

### Feature 5

As illustrated in FIG. 1, no other terminal is disposed between the upper arm collector terminal 1 (first terminal) and the lower arm emitter terminal 4 (second terminal) of each semiconductor chip group, and the terminals are disposed adjacent to each other. With such a configuration, a snubber capacitor can be provided between the frame 2 (first frame) and the frame 5 (second frame), or between the upper arm collector terminal 1 and the lower arm emitter terminal 4. As the snubber capacitor is provided, parasitic inductance can be further reduced, and the surge voltage can be further reduced.

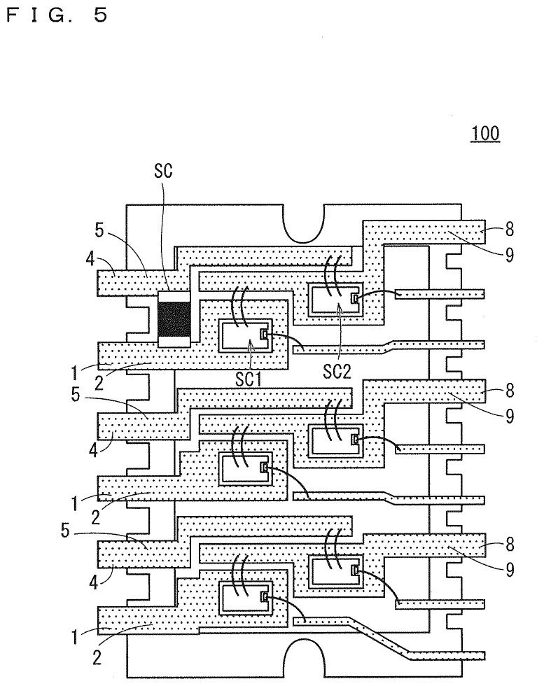

FIG. 5 illustrates an example in which a snubber capacitor SC is provided between the frame 2 and the frame 5 in the resin package PG. The distance between the frame 2 and the frame 5 is designed to be as short as possible, but is designed to be an insulation distance that can ensure the withstand voltage required by the voltage rating of the semiconductor module 100.

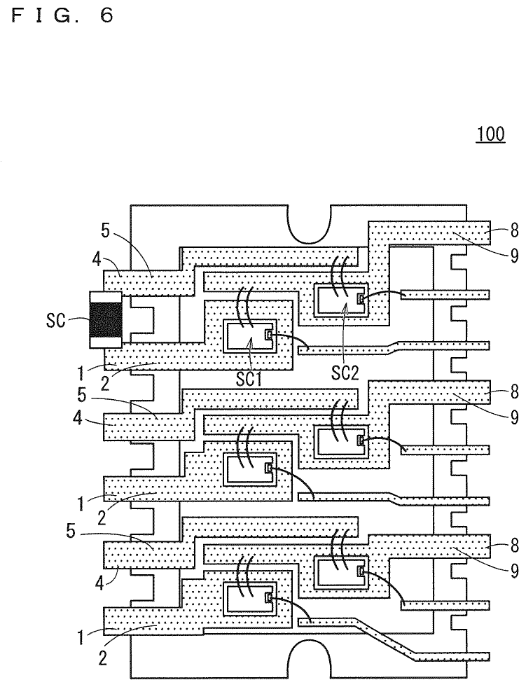

FIG. 6 illustrates an example in which the snubber capacitor SC is provided between the upper arm collector terminal 1 and the lower arm emitter terminal 4. The distance between the upper arm collector terminal 1 and the lower arm emitter terminal 4 is designed to be as short as possible, but is designed to be an insulation distance that can ensure the withstand voltage required by the voltage rating of the semiconductor module 100.

In both examples, the snubber capacitor SC as a measure against the surge can be disposed in the close vicinity of the semiconductor chips.

### Feature 6

As illustrated in FIG. 1, the upper arm collector terminal 1 and the lower arm emitter terminal 4 protrude outward from one side surface of the resin package PG in each phase. Thus, a sufficient terminal width and a sufficient internal wiring width can be secured, and the wiring inductance in the semiconductor module 100 can be reduced.

Further, as described with reference to FIGS. 5 and 6, a snubber capacitor can be provided for each phase, and the capacity of one snubber capacitor can be reduced. If the capacity of each snubber capacitor can be reduced, the size of each snubber capacitor can be made smaller.

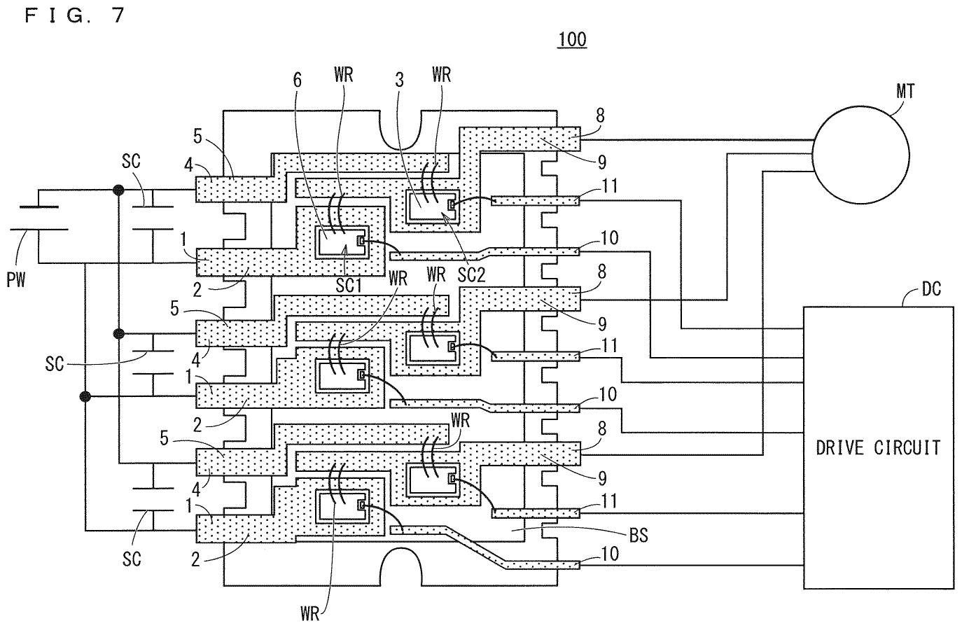

FIG. 7 is a diagram illustrating an example of the external circuits in a case where a snubber capacitor is provided for each phase. As illustrated in FIG. 7, a snubber capacitor SC is provided between the upper arm collector terminal 1 and the lower arm emitter terminal 4 of each phase. The upper arm collector terminal 1 of each phase is connected to a positive terminal of a direct-current power supply PW, and the lower arm emitter terminal 4 of each phase is connected to a negative terminal of the direct-current power supply PW. The upper arm emitter terminal/lower arm collector terminal 8, which is an output terminal of each phase, is connected to a wire of each phase of a motor MT that is a load, and the control terminals 10 and 11 of each phase are connected to a drive circuit DC for the semiconductor chips.

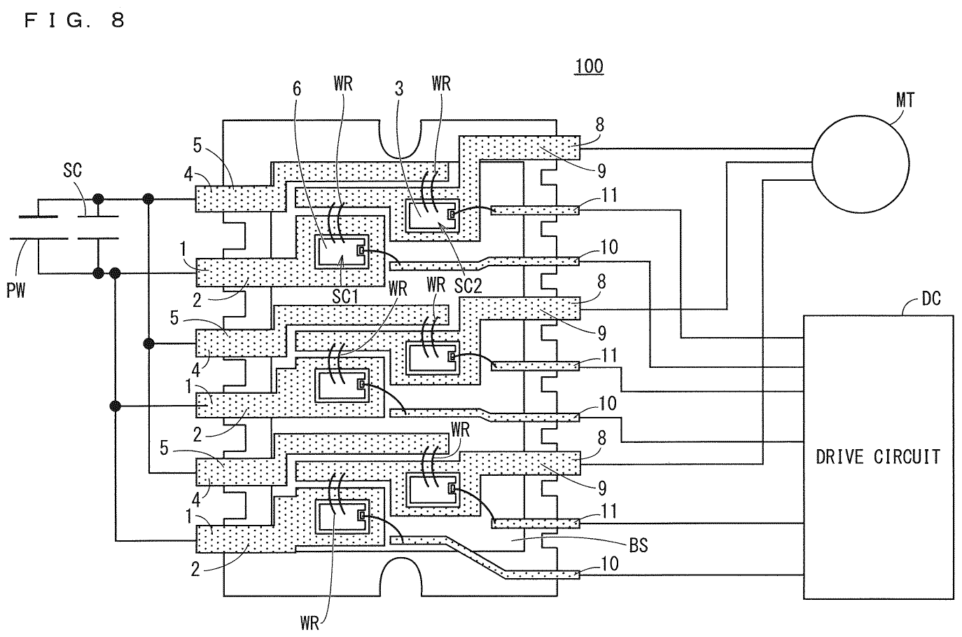

Instead of providing a snubber capacitor for each phase, it is possible to use one snubber capacitor in the three phases. FIG. 8 is a diagram illustrating an example of the external circuits in a case where one snubber capacitor is used in the three phases. As illustrated in FIG. 8, a snubber capacitor SC is connected in parallel to the direct-current power supply PW. The other components are the same as those in FIG. 7. With this arrangement, the number of snubber capacitors can be reduced, and the external circuits can be simplified.

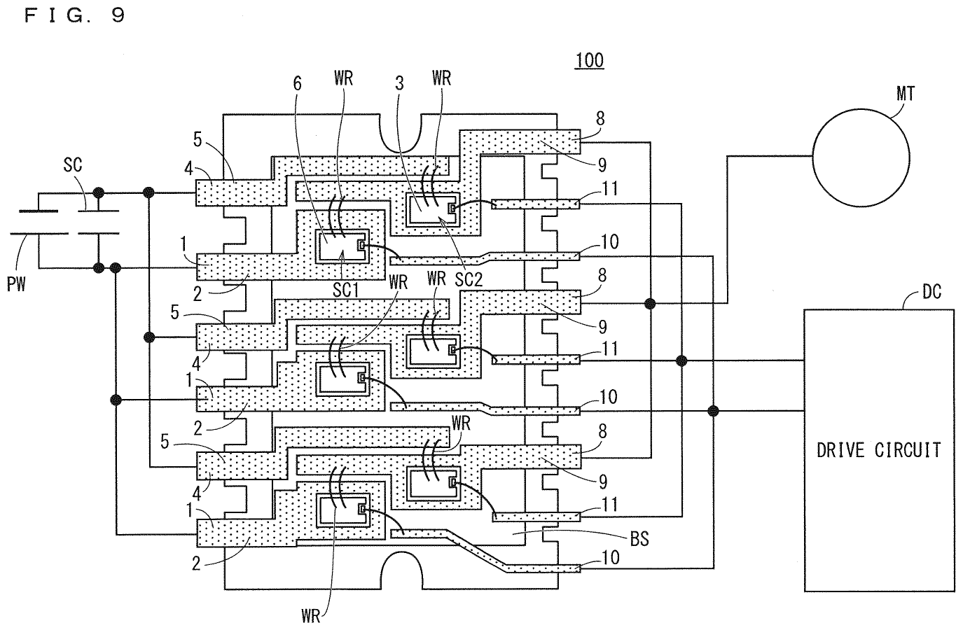

Alternatively, one semiconductor module 100 can be used as a semiconductor module for one phase. FIG. 9 is a diagram illustrating an example of the external circuits in a case where one semiconductor module 100 is used as a semiconductor module for one phase. As illustrated in FIG. 9, the three upper arm emitter terminals/lower arm collector terminals 8 are connected together and are connected to a wire of any phase of the motor MT as a load, and all the control terminals 10 and all the control terminals 11 are connected together and are connected to the drive circuit DC for the semiconductor chips. The other components are the same as those in FIG. 8. By using a plurality of semiconductor chip groups in the semiconductor module 100 as semiconductor chips for one phase, it is possible to increase the amount of power that can be used.

Further, it is possible to facilitate parallel connection of a plurality of semiconductor modules 100 by making the upper arm collector terminal 1 and the lower arm emitter terminal 4 of each phase protrude outward.

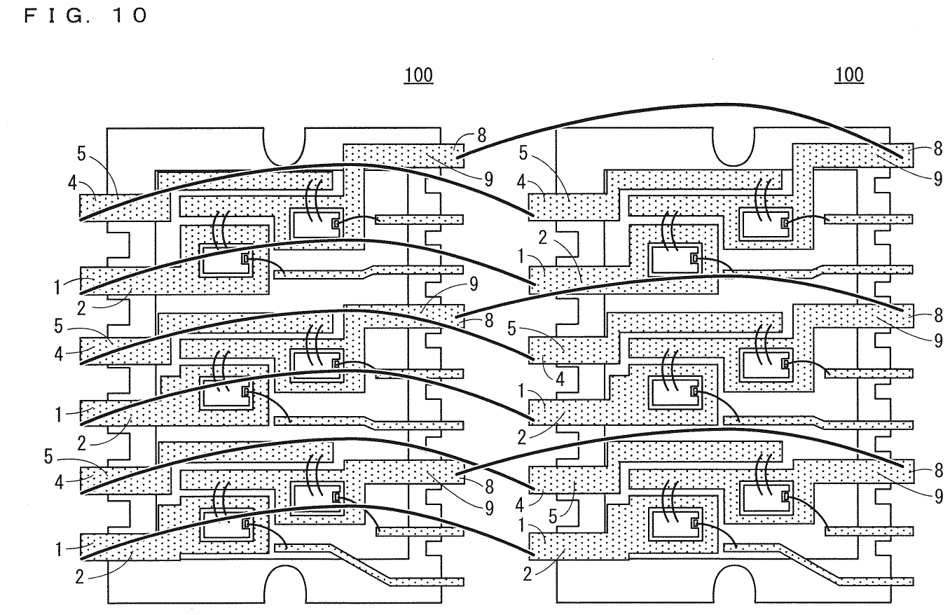

FIG. 10 is a conceptual diagram illustrating an example in which two semiconductor modules 100 are connected in parallel. As illustrated in FIG. 10, of the two semiconductor modules 100, the upper arm collector terminals 1 of each phase are electrically connected to each other, the lower arm emitter terminals 4 of each phase are electrically connected to each other, and the upper arm emitter terminals/lower arm collector terminals 8 of each phase are electrically connected to each other by outer wires OW, so that the two semiconductor modules 100 can be connected in parallel, and wiring inductance can be reduced.

### First Modification

In the semiconductor module 100 illustrated in FIG. 1, as described with reference to FIG. 2, the current-flowing directions are opposite to each other in the opposing portions at which the frame 5 and the frame 9 are arranged so as to be parallel to the current-flow directions, and the emitter electrode 6 of each semiconductor chip SC1 is electrically connected to the frame 9 (third frame) via a wire WR. However, it is possible to lengthen the current path in the frame 9 by changing the position at which the wire WR is connected to the frame 9. Likewise, it is possible to lengthen the current path in the frame 5 by changing the position of the wire WR electrically connecting the emitter electrode 3 and the frame 5 of each semiconductor chip SC2.

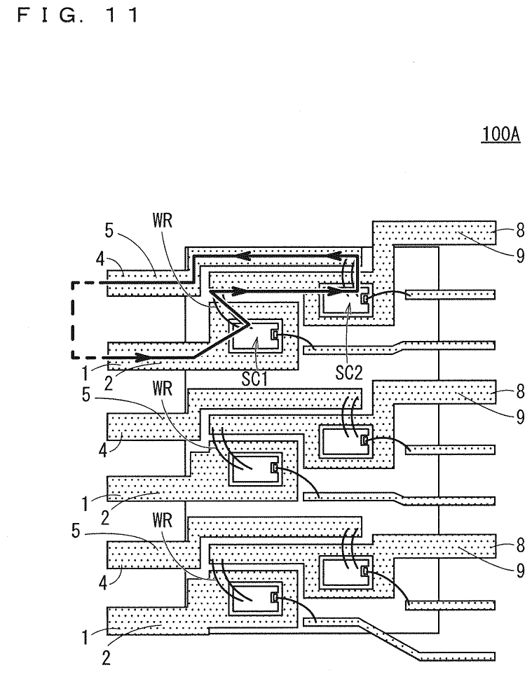

FIG. 11 is a plan view illustrating a configuration of a semiconductor module 100A according to a first modification of the first preferred embodiment. Note that, in FIG. 11, the same components as those of the semiconductor module 100 described with reference to FIG. 1 are denoted by the same reference numerals as those in FIG. 1, and the same explanation will not be repeated.

As illustrated in FIG. 11, the wire WR electrically connecting the emitter electrode 6 and the frame 9 of each semiconductor chip SC1 is connected to the end portion farthest from the upper arm emitter terminal/lower arm collector terminal 8 (third terminal) in the extended portion provided in the frame 9. Likewise, the wire WR electrically connecting the emitter electrode 3 and the frame 5 of each semiconductor chip SC2 is connected to the end portion farthest from the lower arm emitter terminal 4 (second terminal) of the frame 5. With this arrangement, the current path in the opposing portions of the frame 5 and the frame 9 can be lengthened as indicated by arrows in FIG. 11, and parasitic inductance can be further reduced. Thus, the surge voltage to be generated from parasitic inductance can be further reduced.

### Second Modification

In the configuration of the semiconductor module 100 illustrated in FIG. 1, the upper arm collector terminals 1 (first terminals), the lower arm emitter terminals 4 (second terminals), and the upper arm emitter terminals/lower arm collector terminals 8 (third terminals) protrude in horizontal directions from side surfaces of the resin package PG. However, by bending the frame shape at a right angle, it is possible to make these terminals protrude in directions other than horizontal directions from the inside of the resin package PG. For example, it is also possible to make these terminals protrude from one side of the upper surface or the lower surface of the resin package PG. The same applies to the control terminals 10 (fourth terminals) and the control terminals 11 (fifth terminals). By changing the protruding directions of the terminals, it is possible to increase variations of usage of the semiconductor module 100.

### Second Preferred Embodiment

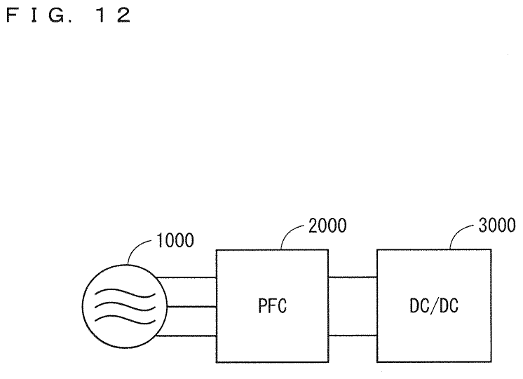

The present preferred embodiment relates to a semiconductor module system in which the semiconductor module according to the above-described first preferred embodiment is applied to a power factor corrector, and FIG. 12 is a block diagram illustrating a configuration of the semiconductor module system according to the second preferred embodiment.

The semiconductor module system illustrated in FIG. 12 includes a three-phase alternating-current power supply 1000, a power factor corrector 2000, and a DC-DC converter 3000. The power factor corrector 2000 is a circuit that brings the power factor of the alternating-current power supply 1000 close to 1, and is called a power factor correction (PFC) circuit.

The semiconductor module 100 described in the first preferred embodiment is used as a three-phase full-bridge converter for the power factor corrector 2000, so that internal inductance can be reduced. Furthermore, as the single semiconductor module 100 is as the three-phase full-bridge converter, routing of wires around the power factor corrector 2000 can be optimized, and inductance in the entire system can be reduced. As a result, the surge voltage can be reduced, and security of the entire system can be enhanced.

Note that, in the present disclosure, the respective preferred embodiments can be freely combined, and each preferred embodiment can be appropriately modified or omitted, within the scope of the disclosure.

The present disclosure described so far is summarized below as Appendixes.

### Appendix 1

A semiconductor module comprising a plurality of semiconductor chip groups each including a first semiconductor chip and a second semiconductor chip that are connected in series between a first power line to which a first voltage is supplied and a second power line to which a second voltage lower than the first voltage is supplied, and perform switching complementarily, wherein
each of the semiconductor chip groups includes:
a first frame that is connected to a lower-surface electrode of the first semiconductor chip, and includes a first terminal that is a portion protruding from the semiconductor module to outside;
a second frame that is connected to an upper-surface electrode of the second semiconductor chip, and includes a second terminal that is a portion protruding from the semiconductor module to the outside;
a third frame that is connected to an upper-surface electrode of the first semiconductor chip and a lower-surface electrode of the second semiconductor chip, and includes a third terminal that is a portion protruding from the semiconductor module to the outside;
a fourth terminal that is connected to a gate electrode of the first semiconductor chip, and protrudes from the semiconductor module to the outside; and
a fifth terminal that is connected to a gate electrode of the second semiconductor chip, and protrudes from the semiconductor module to the outside, and
the semiconductor module has at least either
first opposing portions disposed so as to be parallel to a current-flowing direction in the second frame and the third frame, or
second opposing portions disposed so as to be parallel to the current-flowing direction in the first frame of one of adjacent semiconductor chip groups of the plurality of semiconductor chip groups and in the second frame of another one of the adjacent semiconductor chip groups.

### Appendix 2

The semiconductor module according to Appendix 1, wherein

the third frame has an extended portion extending in parallel to the second frame, from a portion on which the second semiconductor chip is mounted, in the first opposing portion.

### Appendix 3

The semiconductor module according to Appendix 2, wherein
a distance between the second frame and the third frame at the first opposing portions is set to a shortest distance that can ensure a withstand voltage required by a voltage rating of the semiconductor module.

### Appendix 4

The semiconductor module according to Appendix 1, wherein,
in the plurality of semiconductor chip groups,
the first terminals and the second terminals are alternately arranged side by side on a first side of the semiconductor module, and
the third terminals, the fourth terminals, and the fifth terminals are alternately arranged side by side on a second side that is an opposite side of the semiconductor module from the first side, to constitute the semiconductor module.

### Appendix 5

The semiconductor module according to Appendix 1, wherein the first terminal and the second terminal in each semiconductor chip group are disposed adjacent to each other.

### Appendix 6

The semiconductor module according to any one of Appendixes 1 to 5, wherein,
in each of the semiconductor chip groups,
the first terminal and the second terminal protrude from the semiconductor module to the outside separately from each other.

### Appendix 7

The semiconductor module according to any one of Appendixes 1 to 5, wherein
the upper-surface electrode of each first semiconductor chip is electrically connected to an end portion farthest from the third terminal in the third frame, and
the upper-surface electrode of each second semiconductor chip is electrically connected to an end portion farthest from the second terminal in the second frame.

### Appendix 8

A semiconductor module system comprising:
an alternating-current power supply;
a power factor corrector that is connected to the alternating-current power supply, and includes the semiconductor module according to any one of Appendixes 1 to 5; and
a DC-DC converter connected to the power factor corrector.

While the disclosure has been shown and described in detail, the foregoing description is in all aspects illustrative and not restrictive. It is therefore understood that numerous modifications and variations can be devised.

What is claimed is:

1. A semiconductor module comprising a plurality of semiconductor chip groups each including a first semiconductor chip and a second semiconductor chip that are connected in series between a first power line to which a first voltage is supplied and a second power line to which a second voltage lower than the first voltage is supplied, and perform switching complementarily, wherein
each of the semiconductor chip groups includes:
a first frame that is connected to a lower-surface electrode of the first semiconductor chip, and includes a first terminal that is a portion protruding from the semiconductor module to outside;
a second frame that is connected to an upper-surface electrode of the second semiconductor chip, and includes a second terminal that is a portion protruding from the semiconductor module to the outside;
a third frame that is connected to an upper-surface electrode of the first semiconductor chip and a lower-surface electrode of the second semiconductor chip, and includes a third terminal that is a portion protruding from the semiconductor module to the outside;
a fourth terminal that is connected to a gate electrode of the first semiconductor chip, and protrudes from the semiconductor module to the outside; and
a fifth terminal that is connected to a gate electrode of the second semiconductor chip, and protrudes from the semiconductor module to the outside, and
the semiconductor module has at least either
first opposing portions disposed so as to be parallel to a current-flowing direction in the second frame and the third frame, or
second opposing portions disposed so as to be parallel to the current-flowing direction in the first frame of one of adjacent semiconductor chip groups of the plurality of semiconductor chip groups and in the second frame of another one of the adjacent semiconductor chip groups.

2. The semiconductor module according to claim 1, wherein
the third frame has an extended portion extending in parallel to the second frame, from a portion on which the second semiconductor chip is mounted, in the first opposing portion.

3. The semiconductor module according to claim 2, wherein
a distance between the second frame and the third frame at the first opposing portions is set to a shortest distance that can ensure a withstand voltage required by a voltage rating of the semiconductor module.

4. The semiconductor module according to claim 1, wherein,
in the plurality of semiconductor chip groups,
the first terminals and the second terminals are alternately arranged side by side on a first side of the semiconductor module, and
the third terminals, the fourth terminals, and the fifth terminals are alternately arranged side by side on a second side that is an opposite side of the semiconductor module from the first side, to constitute the semiconductor module.

5. The semiconductor module according to claim 1, wherein the first terminal and the second terminal in each semiconductor chip group are disposed adjacent to each other.

6. The semiconductor module according to claim 1, wherein,
in each of the semiconductor chip groups,
the first terminal and the second terminal protrude from the semiconductor module to the outside separately from each other.

7. The semiconductor module according to claim 1, wherein
the upper-surface electrode of each first semiconductor chip is electrically connected to an end portion farthest from the third terminal in the third frame, and
the upper-surface electrode of each second semiconductor chip is electrically connected to an end portion farthest from the second terminal in the second frame.

8. A semiconductor module system comprising:
an alternating-current power supply;
a power factor corrector that is connected to the alternating-current power supply, and includes the semiconductor module according to claim 1; and
a DC-DC converter connected to the power factor corrector.
